(19) United States
(12) Patent Application Publication
(10) Pub. No.: US 2013/0334551 A1
(43) Pub. Date: Dec. 19, 2013

(54) LIGHT-EMITTING DEVICE AND METHOD FOR MANUFACTURING THE SAME

(71) Applicants: Rong-Ren LEE, Hsinchu (TW); Cheng-Hong CHEN, Hsinchu (TW); Chih-Peng NI, Hsinchu (TW); Chun-Yu LIN, Hsinchu (TW)

(72) Inventors: Rong-Ren LEE, Hsinchu (TW); Cheng-Hong CHEN, Hsinchu (TW); Chih-Peng NI, Hsinchu (TW); Chun-Yu LIN, Hsinchu (TW)

(73) Assignee: EPISTAR CORPORATION, Hsinchu (TW)

(21) Appl. No.: 13/517,830

(22) Filed: Jun. 14, 2012

(51) Int. Cl. H01L 33/60; H01L 33/48

(52) U.S. Cl. 257/98; 438/26; 257/E33.06; 257/E33.056

(57) ABSTRACT

A light-emitting device comprising: a substrate having a first surface and a second surface, wherein the second surface is opposite to the first surface; a semiconductor structure formed on the first surface of the substrate, comprising a first type semiconductor layer, an active layer and a second type semiconductor layer; and an isolation region separating at least the active layer into a first part and a second part, wherein the first part is capable of generating the electromagnetic radiation, and the second part comprises a breakdown diode.

### TECHNICAL FIELD

The present application relates to a light-emitting device and a method for manufacturing the same, and more particularly to an III-V compound semiconductor light-emitting device with a breakdown diode in the partial region of the active layer.

### BACKGROUND

The light radiation theory of light-emitting device is to generate light from the energy released by the electrons moving between the n-type semiconductor layer and the p-type semiconductor layer. Because the light radiation theory of light-emitting device is different from the incandescent light which heats the filament, the light-emitting device is called a “cold” light source.

The light-emitting device mentioned above may be mounted with the substrate upside down onto a submount via a solder bump or a glue material to form a light-emitting apparatus. Besides, the submount further comprises one circuit layout electrically connected to the electrode of the light-emitting device via an electrical conductive structure such as a metal wire.

Moreover, the light-emitting device is more sustainable, long-lived, light and handy, and less power consumption, therefore it is considered as a new light source for the illumination market. The light-emitting device applies to various applications like the traffic signal, backlight module, street light and medical instruments, and is gradually replacing the traditional lighting sources.

### SUMMARY

The present application provides a light-emitting device comprising: a substrate having a first surface and a second surface, wherein the second surface is opposite to the first surface; a semiconductor structure formed on the first surface of the substrate, comprising a first type semiconductor layer, an active layer and a second type semiconductor layer; and an isolation region separating at least the active layer into a first part and a second part, wherein the first part is capable of generating the electromagnetic radiation, and the second part comprises a breakdown diode.

The present application provides a method for manufacturing a light-emitting device comprising the steps of: providing a first substrate; forming a semiconductor structure on the first substrate, comprising a first type semiconductor layer, an active layer and a second type semiconductor layer; forming an isolation region separating at least the active layer into a first part and a second part; and injecting an electrical current to enable the first part to generate the electromagnetic radiation and cause the second part broken-down

### BRIEF DESCRIPTION OF THE DRAWINGS

The foregoing aspects and many of the attendant advantages of this application are more readily appreciated as the same become better understood by reference to the following detailed description, when taken in conjunction with the accompanying drawings, wherein:

FIG. 1A through FIG. 1G are schematic diagrams showing the process flow for manufacturing a light-emitting device in accordance with a first embodiment of the present application;

FIG. 2A is a schematic diagram showing the current path for testing a light-emitting device in accordance with a first embodiment of the present application;

FIG. 2B is a schematic diagram showing the I-V test for a light-emitting device in accordance with a first embodiment of the present application;

FIG. 3A through FIG. 3I are schematic diagrams showing the process flow for manufacturing a light-emitting device in accordance with a second embodiment of the present application;

FIG. 4A through FIG. 4I are schematic diagrams showing the process flow for manufacturing a light-emitting device in accordance with a third embodiment of the present application;

FIG. 5 is a schematic diagram of a backlight module device in accordance with a fourth embodiment of the present application; and

FIG. 6 is a schematic diagram of an illumination device in accordance with a fifth embodiment of the present application.

### DETAILED DESCRIPTION OF THE PREFERRED EMBODIMENTS

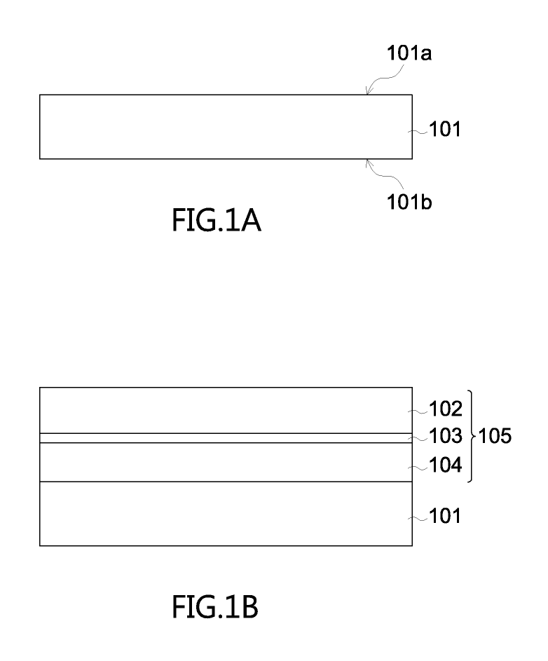

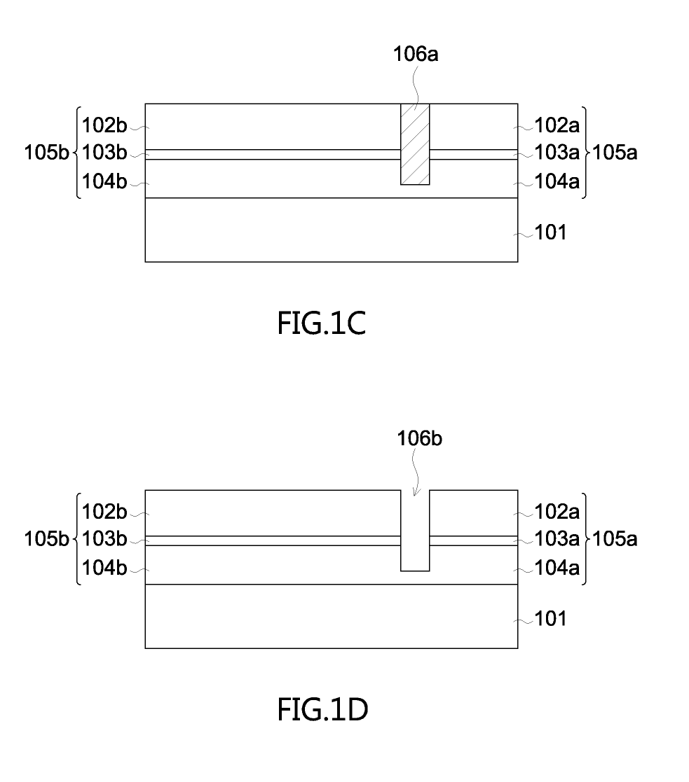

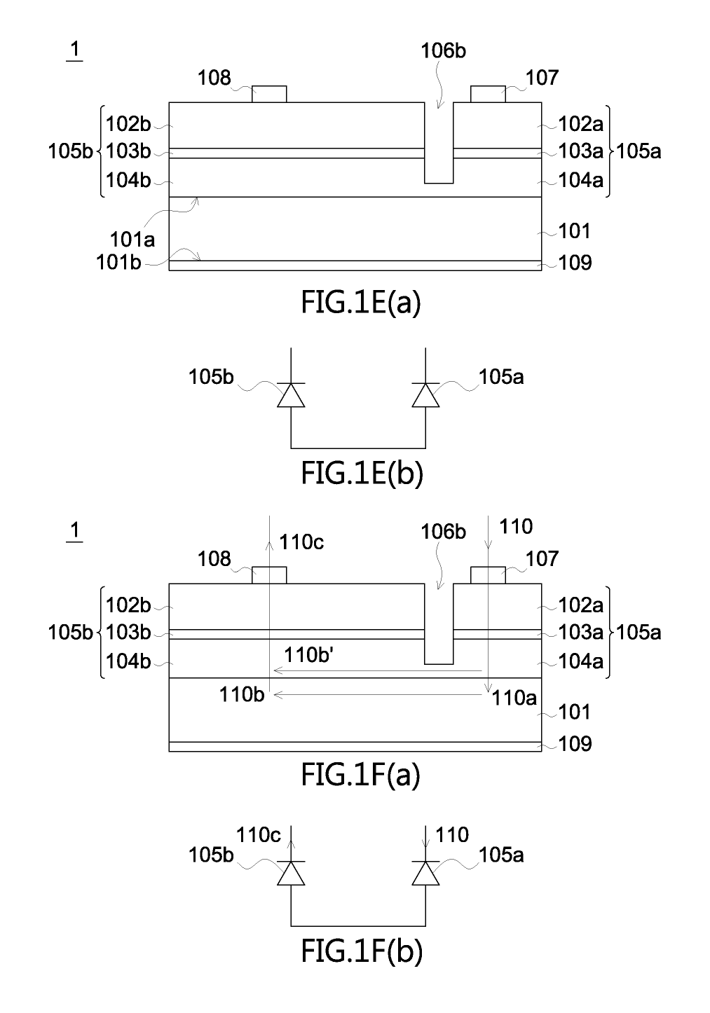

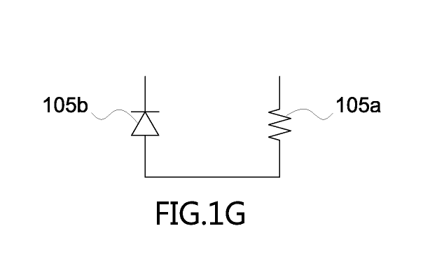

The present application discloses a light-emitting device and a method for manufacturing the same. In order to make the illustration of the present application more explicit, the following description is stated with reference to FIG. 1 through FIG. 6.

FIG. 1A through FIG. 1G are schematic diagrams showing the process flow for manufacturing a light-emitting device 1 in accordance with a first embodiment of the present application. As FIG. 1A shows, a substrate 101 is provided for epitaxial growth, wherein the substrate 101 having a first surface 101a and a second surface 101b. In the embodiment, the material of the substrate 101 may be GaAs. A semiconductor structure 105 is grown on the first surface 101a of the substrate 101 by, for example, metal organic chemical vapor deposition (MOCVD) method, liquid phase deposition (LPD) method, or molecular beam epitaxy (MBE) method. The semiconductor structure 105 comprises a second type semiconductor layer 104, an active layer 103, and a first type semiconductor layer 102 stacked on the first surface 101a of the substrate 101, as shown in FIG. 1B. In the embodiment, the first type semiconductor layer 102 is n-type AlGaInP series material, the active layer 103 is AlGaInP series material, and the second type semiconductor layer 104 is p-type AlGaInP series material. As FIG. 1C shows, an isolation region 106a penetrating the active layer 103 in the semiconductor structure 105 is formed by an ion implantation. The isolation region 106a separates the semiconductor structure 105 into a first part 105b and the second part 105a so the active layer 103 is also separated into a first part 103b and a second part 103a. In another embodiment, the isolation region comprises a trench 106b formed by a wet etching or a dry etching, as shown in FIG. 1D. A second electrode 108 is formed on the first type semiconductor layer 102b of the first part of the semiconductor structure 105b, and a first electrode 107 is formed on the first type semiconductor layer 102a of the second part of the semiconductor structure 105a, so the second electrode 108 and the first electrode 107 are the same conductivity type. The first electrode 107 and the second electrode 108 can be formed simultaneously with the same material. A third electrode 109 is formed on the second surface 101b of the substrate 101 as shown in FIG. 1E(a). The third electrode 109 electrically connects with the second type semiconductor layer 104 so its conductivity type is different from the second electrode 108 and the first electrode 107. The material of the electrodes 107, 108 and 109 comprises metal material such as Cr, Ti, Ni, Pt, Cu, Au, Al, W, Sn, or Ag. FIG. 1E(b) is an equivalent-circuit diagram of the light-emitting device 1. An electrical current injected to the first electrode 107 causes a reverse-bias to the second part of the semiconductor structure 105a and a forward-bias to the first part of the semiconductor structure 105b, wherein the electrical current is a high density current from a power supply. In other words, a high current density current 110 is injected to the first electrode 107 and goes through the light-emitting device 1, and the paths of the current 110 are shown in FIG. 1F(a). The current 110 goes through the second part of the semiconductor structure 105a from the first type semiconductor layer 102a to the second type semiconductor layer 104a to form a path 110a, goes through the substrate 101 horizontally to form a path 110b, goes through the second type semiconductor layer 104 below the trench 106b region horizontally to form a path 110b′, and flows to the second electrode 108 through the first part of the semiconductor structure 105b from the second type semiconductor layer 104b to the first type semiconductor layer 102b to form a path 110c. In the embodiment, the current density of the current 110 is greater than 80 A/cm². FIG. 1F(b) is an equivalent-circuit diagram of the light-emitting device in FIG. 1F(a). Only the first part of the active layer 103b can generate the electromagnetic radiation during operation of the light-emitting device 1 while the second part of the active layer 103a can not generate the electromagnetic radiation because a breakdown diode is formed. FIG. 1G is an equivalent-circuit diagram of the light-emitting device 1 after the high current density current 110 is injected to the first electrode 107 and goes through the light-emitting device 1.

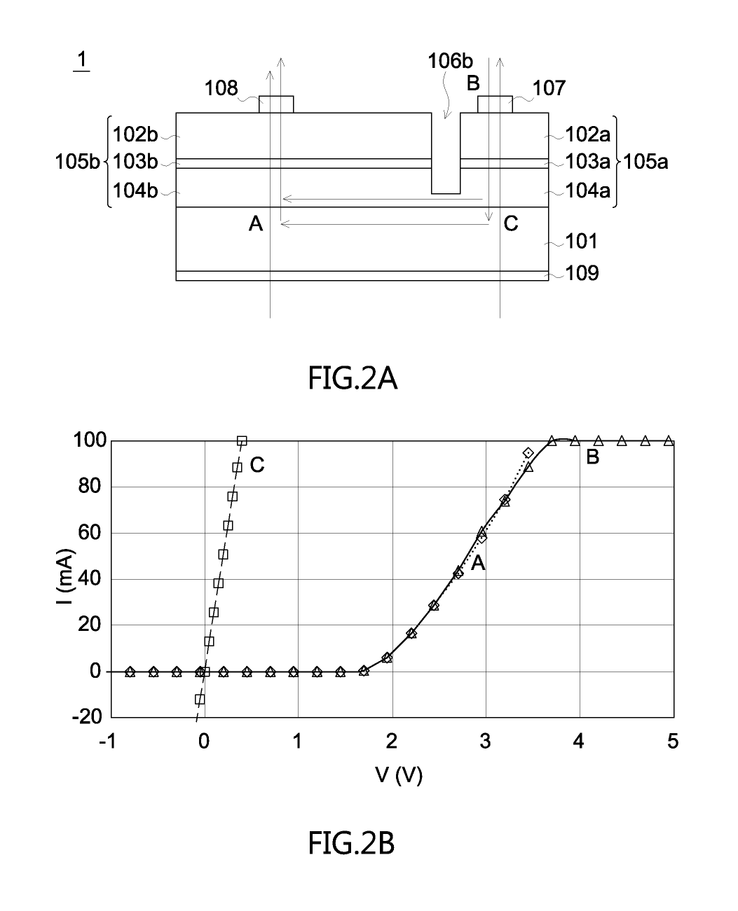

The current paths go through the light-emitting device 1 during the I-V test are shown in FIG. 2A. Injecting a testing current from the third electrode 109 of the light-emitting device 1 through the first part of the semiconductor structure 105b from the second type semiconductor layer 104b to the first type semiconductor layer 102b to form a path A, then obtaining a current vs. voltage curve A as shown in the FIG. 2B. Injecting a testing current from the first electrode 107 to the second electrode 108 through the second part of the semiconductor structure 105a from the first type semiconductor layer 102a to the second type semiconductor layer 104a, through the substrate 101 horizontally and through the second type semiconductor layer 104 below the trench 106b region horizontally respectively, and through the first part of the semiconductor structure 105b from the second type semiconductor layer 104b to the first type semiconductor layer 102b to form a path B, then obtaining a current vs. voltage curve B as shown in the FIG. 2B. Injecting a testing current from the third electrode 109 to the first electrode 107 through the second part of the semiconductor structure 105a from the second type semiconductor layer 104a to the first type semiconductor layer 102a to form a path C, then obtaining a current vs. voltage curve C as shown in the FIG. 2B, which indicates that the second part of the semiconductor structure 105a forms a breakdown diode. The trend of the curve A and the curve B is substantially the same and indicates the electrical property of the path B is the same as the electrical property of the path A in the light-emitting device 1, which means the first part of the semiconductor structure 105b in the light-emitting device 1 can operate normally after the high current density current 110 is injected to the first electrode 107 and flows along the path B.

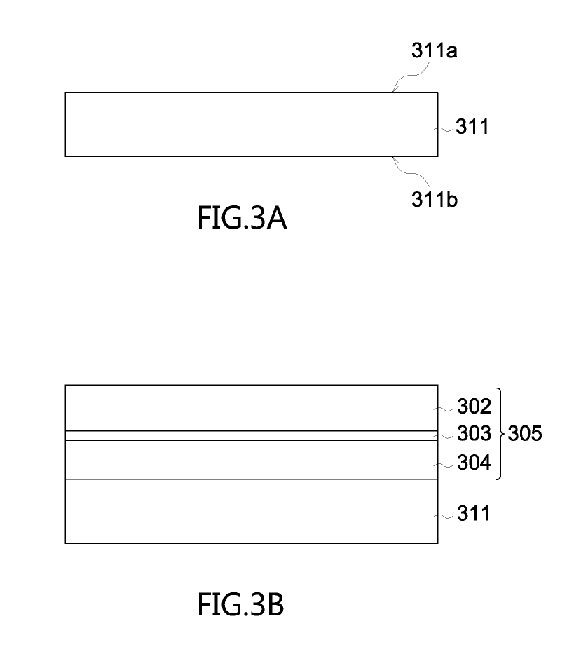

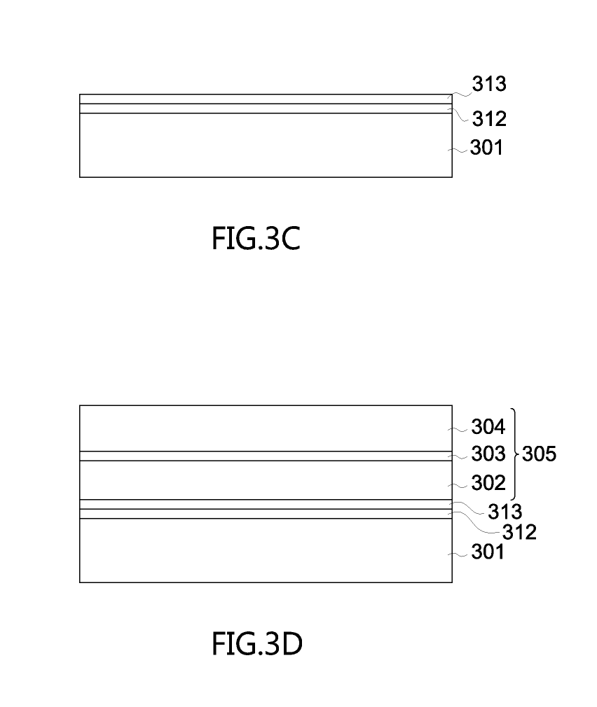

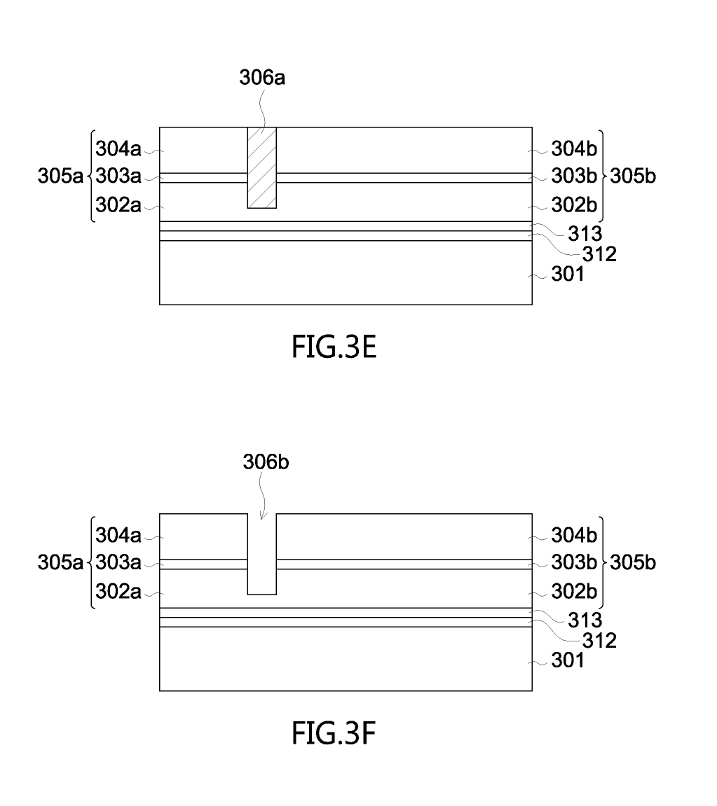

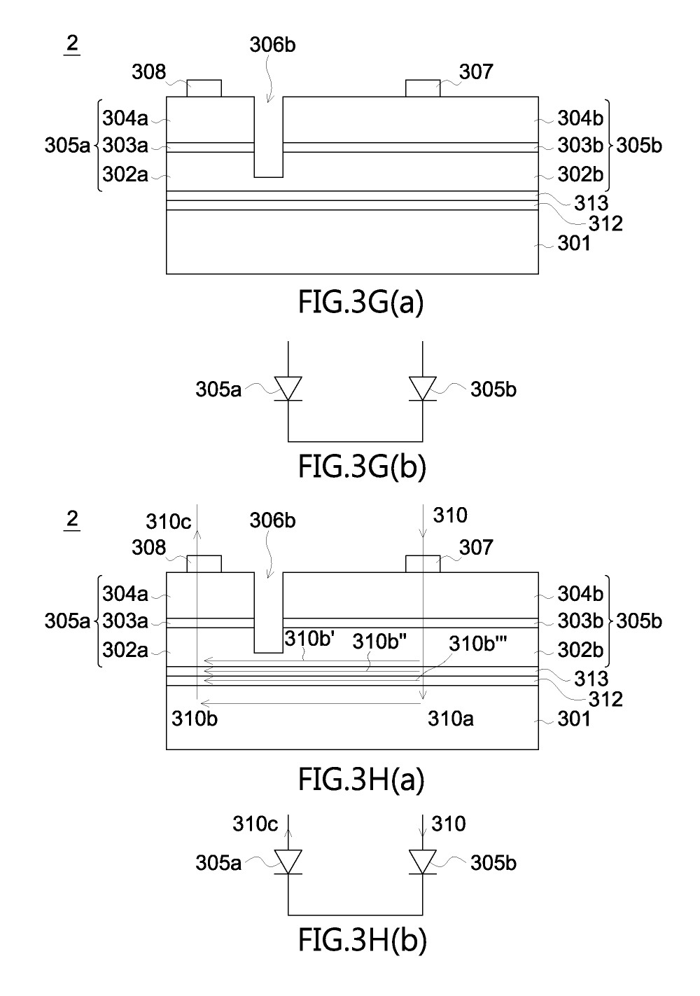

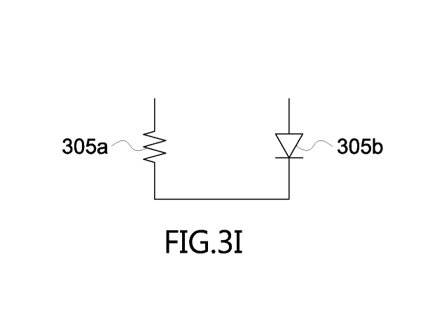

FIG. 3A through FIG. 3I are schematic diagrams showing the process flow for manufacturing a light-emitting device 2in accordance with a second embodiment of the present application. As FIG. 3A shows, a growth substrate 311 is provided for epitaxial growth, wherein the growth substrate 311 having a first surface 311a and a second surface 311b. In the embodiment, the material of the growth substrate 311 may be GaAs. A semiconductor structure 305 is grown on the first surface 311a of the growth substrate 311 by, for example, metal organic chemical vapor deposition (MOCVD) method, liquid phase deposition (LPD) method, or molecular beam epitaxy (MBE) method. The semiconductor structure 305 comprises a second type semiconductor layer 304, an active layer 303, and a first type semiconductor layer 302 stacked on the first surface 311a of the growth substrate 311, as shown in FIG. 3B. In the embodiment, the first type semiconductor layer 302 is n-type AlGaInP series material, the active layer 303 is AlGaInP series material, and the second type semiconductor layer 304 is p-type AlGaInP series material. As FIG. 3C shows, a substrate 301 is provided, a reflecting layer 312 is formed on the substrate 301, and the bonding layer 313 is formed on the reflecting layer 312. In FIG. 3D, the semiconductor structure 305 shown in FIG. 3B is connected with the structure shown in FIG. 3C by the bonding layer 313. Then the growth substrate 311 is removed by selectively etching, lapping, polishing, wafer lift-off, or the combination thereof (not shown).

The substrate 301 is conductive, wherein the material of the substrate 301 comprises metal such as Cu, Al, Mo, metal alloy such as Cu—Sn, Cu—Zn, conductive oxide such as ZnO, SnO, or semiconductor such as Si, AlN, GaAs, SiC, or GaP. The bonding layer 313 is conductive, wherein the material of the bonding layer 313 comprises metal, silver glue, conductive polymer, polymer materials mixed with conductive materials, or anisotropic conductive film.

As FIG. 3E shows, an isolation region 306a penetrating the active layer 303 in the semiconductor structure 305 is formed by an ion implantation. The isolation region 306a separates the semiconductor structure 305 into a first part 305b and the second part 305a so the active layer 303 is also separated into a first part 303b and a second part 303a. In another embodiment, the isolation region comprises a trench 306b formed by a wet etching or a dry etching, as shown in FIG. 3F. A second electrode 308 is formed on the second type semiconductor layer 304a of the second part of the semiconductor structure 305a, and a first electrode 307 is formed on the second type semiconductor layer 304b of the first part of the semiconductor structure 305b, so the second electrode 308 and the first electrode 307 are the same conductivity type. The first electrode 307 and the second electrode 308 can be formed simultaneously with the same material. Then a light-emitting device 2 is formed as shown in FIG. 3G(a). The material of the electrodes 307 and 308 comprises metal material such as Cr, Ti, Ni, Pt, Cu, Au, Al, W, Sn, or Ag. FIG. 3G(b) is an equivalent-circuit diagram of the light-emitting device 2. An electrical current injected to the first electrode 307 causes a reverse-bias to the second part of the semiconductor structure 305a and a forward-bias to the first part of the semiconductor structure 305b, wherein the electrical current is a high density current from a power supply. In other words, a high current density current 310 is injected to the first electrode 307 and goes through the light-emitting device 2, and the paths of the current 310 are shown in FIG. 3H(a). The current 310 goes through the first part of the semiconductor structure 305b from the second type semiconductor layer 304b to the first type semiconductor layer 302b to form a path 310a, goes through the substrate 301 horizontally to form a path 310b, goes through the first type semiconductor layer 302 below the trench 306b region horizontally to form a path 310b′, goes through the bonding layer 313 horizontally to form a path 310b″, goes through the reflecting layer 312 horizontally to form a path 310b′″ and flows to the second electrode 308 through the second part of the semiconductor structure 305a from the first type semiconductor layer 302a to the second type semiconductor layer 304a to form a path 310c. In the embodiment, the current density of the current 310 is greater than 80 A/cm². FIG. 3H(b) is an equivalent-circuit diagram of the light-emitting device in FIG. 3H(a). Only the first part of the active layer 303b can generate the electromagnetic radiation during operation of the light-emitting device 2 while the second part of the active layer 303a can not generate the electromagnetic radiation because a breakdown diode is formed. FIG. 3I is an equivalent-circuit diagram of the light-emitting device 2 after the high current density current 310 is injected to the first electrode 307 and goes through the light-emitting device 2.

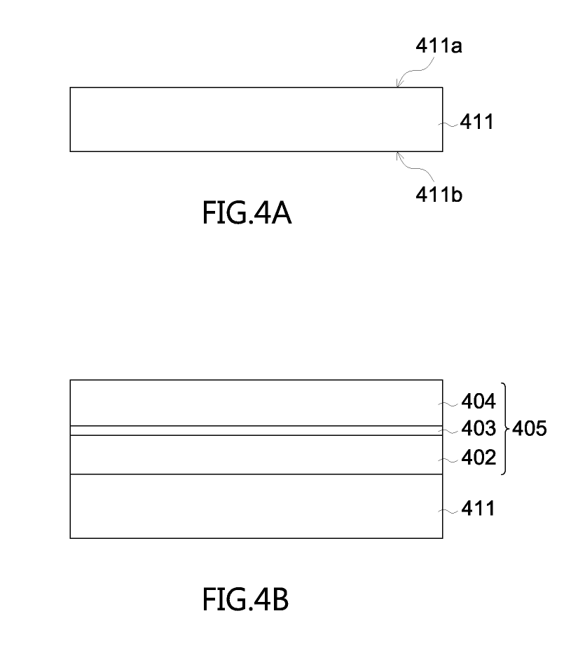

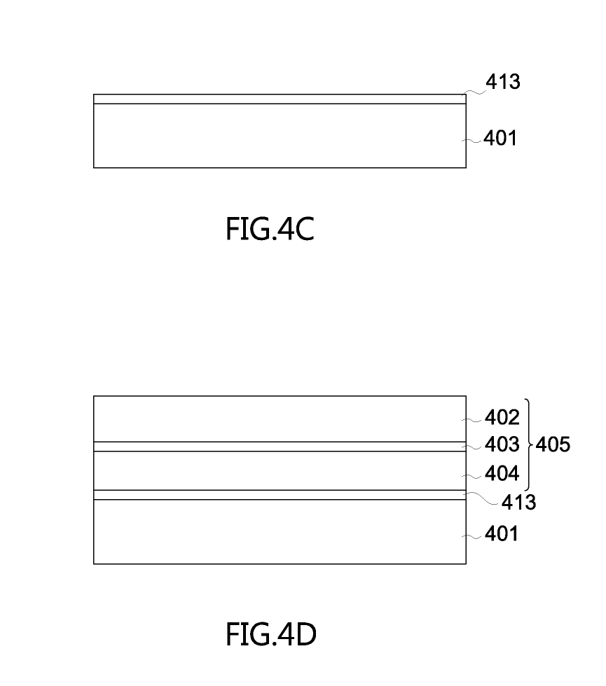

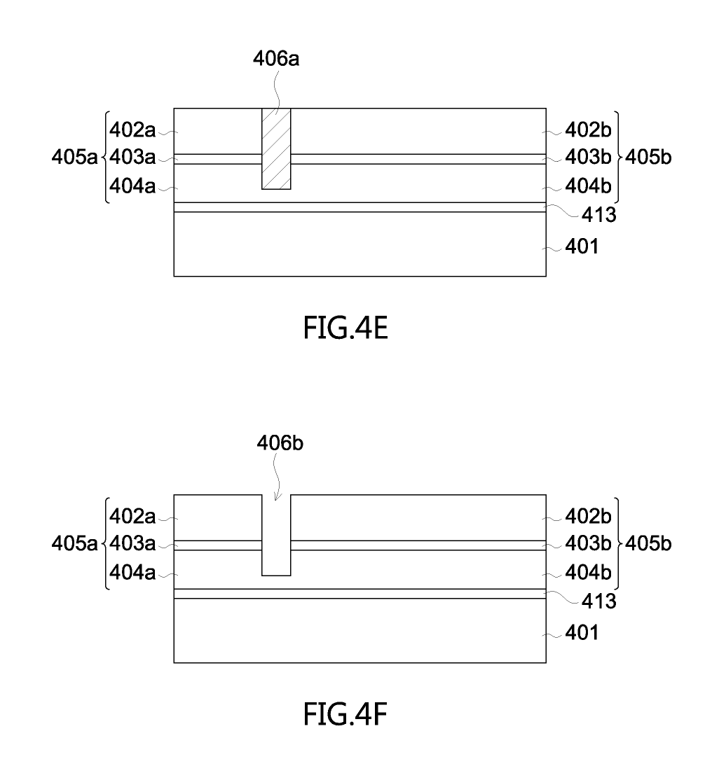

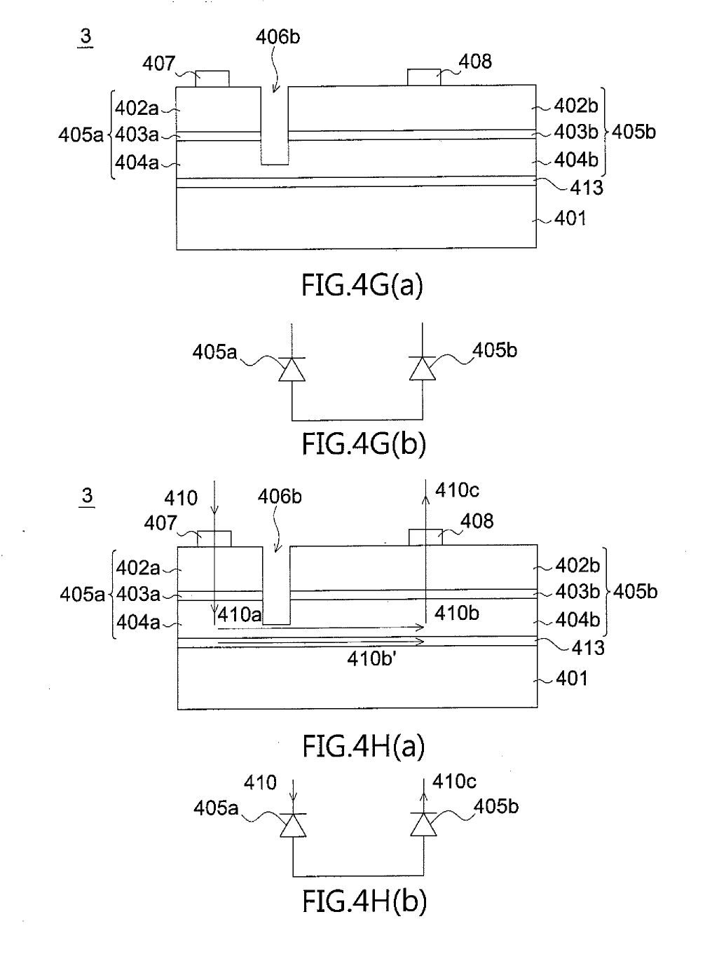

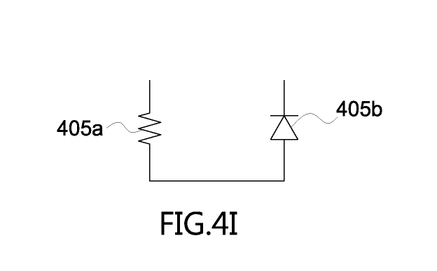

FIG. 4A through FIG. 4I are schematic diagrams showing the process flow for manufacturing a light-emitting device 3 in accordance with a third embodiment of the present application. As FIG. 4A shows, a growth substrate 411 is provided for epitaxial growth, wherein the growth substrate 411 having a first surface 411a and a second surface 411b. In the embodiment, the material of the growth substrate 411 may be GaAs. A semiconductor structure 405 is grown on the first surface 411a of the growth substrate 411 by, for example, metal organic chemical vapor deposition (MOCVD) method, liquid phase deposition (LPD) method, or molecular beam epitaxy (MBE) method. The semiconductor structure 405 comprises a first type semiconductor layer 402, an active layer 403, and a second type semiconductor layer 404 stacked on the first surface 411a of the growth substrate 411, as shown in FIG. 4B. In the embodiment, the first type semiconductor layer 402 is n-type AlGaInP series material, the active layer 403 is AlGaInP series material, and the second type semiconductor layer 404 is p-type AlGaInP series material. As FIG.4C shows, a substrate 401 is provided, and the bonding layer 413 is formed on the substrate 401. In FIG. 4D, the semiconductor structure 405 shown in FIG. 4B is connected with the structure shown in FIG. 4C by the bonding layer 413. Then the growth substrate 411 is removed by selectively etching, lapping, polishing, wafer lift-off, or the combination thereof (not shown).

The substrate 401 is non-conductive, wherein the material of the substrate 401 comprises metal oxide such as sapphire, carbon-containing materials such as diamond, dielectric materials, glass, or polymer such as epoxy. The bonding layer 413 is conductive or non-conductive.

As FIG. 4E shows, an isolation region 406a penetrating the active layer 403 in the semiconductor structure 405 is formed by an ion implantation. The isolation region 406a separates the semiconductor structure 405 into a first part 405b and the second part 405a so the active layer 403 is also separated into a first part 403b and a second part 403a. In another embodiment, the isolation region comprises a trench 406b formed by a wet etching or a dry etching, as shown in FIG. 4F. A second electrode 408 is formed on the first type semiconductor layer 402b of the first part of the semiconductor structure 405b, and a first electrode 407 is formed on the first type semiconductor layer 402a of the second part of the semiconductor structure 405a, so the second electrode 408 and the first electrode 407 are the same conductivity type. The first electrode 407 and the second electrode 408 can be formed simultaneously with the same material. Then a light-emitting device 3 is formed as shown in FIG. 4G(a). The material of the electrodes 407 and 408 comprises metal material such as Cr, Ti, Ni, Pt, Cu, Au, Al, W, Sn, or Ag. FIG. 4G(b) is an equivalent-circuit diagram of the light-emitting device 3. An electrical current injected to the first electrode 407 causes a reverse-bias to the second part of the semiconductor structure 405a and a forward-bias to the first part of the semiconductor structure 405b, wherein the electrical current is a high density current from a power supply. In other words, a high current density current 410 is injected to the first electrode 407 and goes through the light-emitting device 3, and the paths of the current 410 are shown in FIG. 4H(a). The current 410 goes through the second part of the semiconductor structure 405a from the first type semiconductor layer 402a to the second type semiconductor layer 404a to form a path 410a, goes through the second type semiconductor layer 404 below the trench 406b region horizontally to form a path 410b, goes through the bonding layer 413 (formed of conductive material) horizontally to form a path 410b′ and flows to the second electrode 408 through the first part of the semiconductor structure 405b from the second type semiconductor layer 404b to the first type semiconductor layer 402b to form a path 410c. In the embodiment, the current density of the current 410 is greater than 80 A/cm². FIG. 4H(b) is an equivalent-circuit diagram of the light-emitting device in FIG. 4H(a). Only the first part of the active layer 403b can generate the electromagnetic radiation during operation of the light-emitting device 3while the second part of the active layer 403a can not generate the electromagnetic radiation because a breakdown diode is formed. FIG. 4I is an equivalent-circuit diagram of the light-emitting device 3 after the high current density current 410 is injected to the first electrode 407 and goes through the light-emitting device 3.

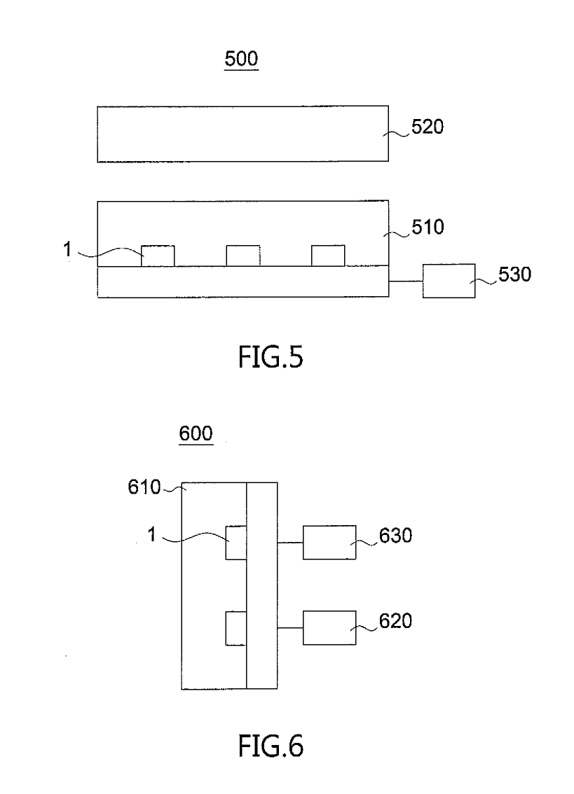

FIG. 5 shows a schematic diagram of a backlight module device 500 in accordance with a fourth embodiment of the present application. The backlight module device 500 comprises a light source device 510 having the light-emitting device 1, 2, or 3 in one of the above mentioned embodiments, an optics device 520 deposited on the light extraction pathway of the light source device 510, and a power supplement 530 which provides a predetermined power to the light source device 510.

FIG. 6 shows a schematic diagram of an illumination device 600 in accordance with a fifth embodiment of the present application. The illumination device 600 can be automobile lamps, street lights, flashlights, indicator lights and so forth. The illumination device 600 comprises a light source device 610 having the light-emitting device 1, 2, or 3 in one of the above mentioned embodiments, a power supplement 620 which provides a predetermined power to the light source device 610, and a control element 630 which controls the current driven into the light source device 610.

In accordance with the embodiments in the application, the first type semiconductor layer 102, 302, or 402 and the second type semiconductor layer of the semiconductor structure 104, 304, or 404 are two single-layer structures or two multiple layers structure (“multiple layers” means two or more than two layers) having different electrical properties, polarities, dopants for providing electrons or holes respectively. If the first type semiconductor layer and the second type semiconductor layer are composed of the semiconductor materials, the conductivity type can be any two of p-type, n-type, and i-type. The active layer 103, 303, or 403 disposed between the first type semiconductor layer 102, 302, or 402 and the second type semiconductor layer 104, 304, or 404 is a region where the light energy and the electrical energy could transfer or could be induced to transfer.

In another embodiment of this application, the light emission spectrum of the semiconductor structure 105, 305, or 405 after transferring can be adjusted by changing the physical or chemical arrangement of one layer or more layers in the active layer. The material of the active layer can be AlGaInP series material or AlGaInN series material. The structure of the active layer can be a single heterostructure (SH), a double heterostructure (DH), a double-side double heterostructure (DDH), or a multi-quantum well (MQW) structure. Besides, the wavelength of the emitted light could also be adjusted by changing the number of the pairs of the quantum well in a MQW structure.

In one embodiment of this application, a buffer layer (not shown) could be optionally formed between the substrate and the semiconductor structure. The buffer layer between two material systems can be used as a buffer system. For the structure of the light-emitting device, the buffer layer is used to reduce the lattice mismatch between two material systems. On the other hand, the buffer layer could also be a single layer, multiple layers, or a structure to combine two materials or two separated structures where the material of the buffer layer can be organic, inorganic, metal, semiconductor, and so on, and the function of the buffer layer can be as a reflection layer, a heat conduction layer, an electrical conduction layer, an ohmic contact layer, an anti-deformation layer, a stress release layer, a stress adjustment layer, a bonding layer, a wavelength converting layer, a mechanical fixing structure, and so on. The material of the buffer layer can be AlN, GaN, InP, GaP or other suitable materials. The fabricating method of the buffer layer can be sputter or atomic layer deposition (ALD).

A contact layer (not shown) can also be optionally formed on the semiconductor structure. The contact layer is disposed on the second type semiconductor layer opposite to the active layer. Specifically speaking, the contact layer could be an optical layer, an electrical layer, or the combination of the two. An optical layer can change the electromagnetic radiation or the light from or entering the active layer. The term “change” here means to change at least one optical property of the electromagnetic radiation or the light. The above mentioned property includes but is not limited to frequency, wavelength, intensity, flux, efficiency, color temperature, rendering index, light field, and angle of view. An electrical layer can change or be induced to change the value, density, or distribution of at least one of the voltage, resistance, current, or capacitance between any pair of the opposite sides of the contact layer. The composition material of the contact layer includes at least one of oxide, conductive oxide, transparent oxide, oxide with 50% or higher transmittance, metal, relatively transparent metal, metal with 50% or higher transmittance, organic material, inorganic material, fluorescent material, phosphorescent material, ceramic, semiconductor, doped semiconductor, and undoped semiconductor. In certain applications, the material of the contact layer is at least one of indium tin oxide (ITO), cadmium tin oxide (CTO), antimony tin oxide, indium zinc oxide, zinc aluminum oxide, and zinc tin oxide. If the material is relatively transparent metal, the thickness is about 0.005 μm-0.6 μm.

It will be apparent to those having ordinary skill in the art that various modifications and variations can be made to the devices in accordance with the present application without departing from the scope or spirit of the disclosure. In view of the foregoing, it is intended that the present application covers modifications and variations of this disclosure provided they fall within the scope of the following claims and their equivalents.

Although the drawings and the illustrations above are corresponding to the specific embodiments individually, the element, the practicing method, the designing principle, and the technical theory can be referred, exchanged, incorporated, collocated, coordinated except they are conflicted, incompatible, or hard to be put into practice together.

Although the present application has been explained above, it is not the limitation of the range, the sequence in practice, the material in practice, or the method in practice.

Any modification or decoration for present application is not detached from the spirit and the range of such.

1. A light-emitting device, comprising:
a substrate having a first surface and a second surface, wherein the second surface is opposite to the first surface;
a semiconductor structure formed on the first surface of the substrate, comprising a first type semiconductor layer, an active layer, and a second type semiconductor layer; and
an isolation region separating the semiconductor structure into a first part and a second part, wherein the first part is capable of generating an electromagnetic radiation, and the second part comprises a breakdown diode that is broken-down.

2. The light-emitting device according to claim 1, further comprising a first electrode and a second electrode on the semiconductor structure.

3. The light-emitting device according to claim 1, further comprising a third electrode on the second surface of the substrate.

4. The light-emitting device according to claim 1, further comprising a bonding layer between the semiconductor structure and the substrate.

5. The light-emitting device according to claim 1, wherein the substrate is conductive or non-conductive.

6. The light-emitting device according to claim 5, further comprising a reflective layer between the semiconductor structure and the substrate.

7. The light-emitting device according to claim 4, wherein the bonding layer is conductive or non-conductive.

8. The light-emitting device according to claim 1, wherein the isolation region comprises a trench.

9. The light-emitting device according to claim 1, wherein the isolation region comprises an ion implanted region.

10. The light-emitting device according to claim 8, wherein the trench comprises an etched region.

11. A method for manufacturing a light-emitting device comprising the steps of:
providing a first substrate;
forming a semiconductor structure on the first substrate, comprising a first type semiconductor layer, an active layer and a second type semiconductor layer;
forming an isolation region separating the semiconductor structure into a first part and a second part; and
injecting an electrical current to cause the second part to be broken-down.

12. The method according to claim 11, wherein injecting an electrical current causes a reverse-bias to the second part and a forward-bias to the first part.

13. The method according to claim 11, further comprising a step of forming a first electrode and a second electrode on the semiconductor structure.

14. The method according to claim 11, further comprising a step of providing a second substrate is for growing the light-emitting structure.

15. The method according to claim 14, further comprising a step of separating the light-emitting structure from the second substrate and bonding to the first substrate.

16. The method according to claim 11, further comprising a step of forming a trench in the isolation region.

17. The method according to claim 11, wherein forming the isolation region comprises an ion implantation.

18. The method according to claim 16, wherein forming the trench by wet etching or a dry etching.

19. The method according to claim 11, wherein the electrical current is a current having a density greater than 80 A/cm².

20. The light-emitting device according to claim 1, wherein the isolation region is formed through the first type semiconductor layer and the active layer, and reaches the second type semiconductor layer.
